(19) United States
(12) Patent Application Publication
(10) Pub. No.: US 2020/0339424 A1
(43) Pub. Date: Oct. 29, 2020

(54) GRAPHENE PRODUCTION METHOD

(71) Applicant: Paragraf Limited, Somersham (GB)

(72) Inventors: Simon Thomas, Somersham (GB); Ivor Guiney, Somersham (GB)

(73) Assignee: Paragraf Limited, Somersham (GB)

(21) Appl. No.: 16/961,646

(22) PCT Filed: Jan. 10, 2019
(86) PCT No.: PCT/GB2019/050059

§ 371 Date: Jul. 10, 2020

(30) Foreign Application Priority Data
Jan. 11, 2018 (GB) 1800447.3

(51) Int. Cl. C01B 32/184; C23C 14/35; C23C 14/02; C23C 14/16

(52) U.S. Cl. CPC C01B 32/184; C23C 14/16; C23C 14/024; C23C 14/35

(57) ABSTRACT

A method for the production of graphene on a substrate, the method comprising providing a substrate having Si—OH and/or Si—H moieties on a surface thereof; providing a carbon-containing reagent; contacting the carbon-containing reagent with the surface of the substrate to form a carbon-containing coating attached to the Si—OH and/or Si—H moieties on the surface; depositing one or more metals onto the coated surface to form a metal layer on the coated surface; and heating the substrate under an inert atmosphere to thereby decompose the carbon-containing coating to form a metal-coated graphene layer on the substrate.

### REFERENCE TO RELATED APPLICATION

This application is a U.S. national stage application based on PCT/GB2019/050059, filed Jan. 10, 2019, claiming priority to Great Britain application no. 1800447.3, filed Jan. 11, 2018, the entire disclosures of which are incorporated herein by reference.

### FIELD OF THE INVENTION

The present invention relates to a method of producing graphene layer structures. In particular, the method of the invention provides an improved method for the provision of large area graphene sheets on relatively low-cost, readily-available substrates.

### BACKGROUND

Graphene is a well-known material with a plethora of proposed applications driven by the material's theoretical extraordinary properties. Good examples of such properties and applications are detailed in ‘The Rise of Graphene’ by A. K. Geim and K. S. Novoselev, Nature Materials, vol. 6, March 2007, 183-191.

WO 2017/029470, the content of which is incorporated herein by reference, discloses methods for producing two-dimensional materials. Specifically, WO 2017/029470 discloses a method of producing two-dimensional materials such as graphene, comprising heating a substrate held within a reaction chamber to a temperature that is within a decomposition range of a precursor, and that allows graphene formation from a species released from the decomposed precursor; establishing a steep temperature gradient (preferably >1000° C. per meter) that extends away from the substrate surface towards an inlet for the precursor; and introducing precursor through the relatively cool inlet and across the temperature gradient towards the substrate surface. The method of WO 2017/029470 may be performed using vapour phase epitaxy (VPE) systems and metal-organic chemical vapour deposition (MOCVD) reactors.

The method of WO 2017/029470 provides two-dimensional materials with a number of advantageous characteristics including: very good crystal quality; large material grain size; minimal material defects; large sheet size; and are self-supporting. However, there remains a need for fast and low-cost processing methods for fabricating devices from the two-dimensional materials.

US 2017/0346010 discloses a method and structure for providing uniform, large-area graphene by way of a transfer-free, direct-growth process. US 2017/0346010 teaches the use of a self-assembled monolayer (SAM) as a carbon source, wherein the SAM is produced using a vapour phase deposition method such as atomic layer deposition (ALD) or molecular layer deposition (MLD).

US 2015/0014600 discloses method for manufacturing high quality graphene by heating carbon-based self-assembly monolayers. Specifically, US 2015/0014600 teaches

US 2013/0099194 discloses a method for forming a graphene layer. The method includes forming an article that comprises a carbon-containing self-assembled monolayer (SAM). A layer of nickel is deposited on the SAM.

### SUMMARY OF THE INVENTION

It is an object of the present invention to provide an improved method for producing large graphene layers which overcome, or substantially reduce, problems associated with the prior art or at least provide a commercially useful alternative thereto.

According to a first aspect there is provided a method for the production of graphene on a substrate, the method comprising:

providing a substrate having Si—OH and/or Si—H moieties on a surface thereof;

providing a carbon-containing reagent;

contacting the carbon-containing reagent with the surface of the substrate to form a carbon-containing coating attached to the Si—OH and/or Si—H moieties on the surface,

depositing one or more metals onto the coated surface to form a metal layer on the coated surface,

heating the substrate under an inert atmosphere to thereby decompose the carbon-containing coating to form a metal-coated graphene layer on the substrate.

### DETAILED DESCRIPTION OF PREFERRED EMBODIMENTS

The present disclosure will now be described further. In the following passages different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The present inventors have provided a new production mechanism for the provision of large-area graphene sheets on relatively low cost, readily available substrates. The method involves activating the surface of fused silica, quartz, other glasses, polymers or plastics with a reaction to generate either Si—H or Si—OH groups. Thereafter, a suitable carbon source is attached to the surface by reacting with an appropriate precursor, for example a silane, silanol or olefin. Subsequent coating of the surface carbon groups with a metal, then annealing, drives the carbon to the surface interface between metal and silica (or quartz or glass) resulting in the formation of graphene. Optional etching of the metal layer from the surface will leave just a substrate and surface-formed graphene.

As will be appreciated, the metal layer catalyses the decomposition of the carbon-containing compound to form the graphene. This means that a homogeneous large-sized graphene layer can be formed directly on the substrate.

The method is for the production of graphene on a substrate. Graphene is a well-known term in the art and refers to an allotrope of carbon comprising a single layer of carbon atoms in a hexagonal lattice. The term graphene used herein encompasses structures comprising multiple graphene layers stacked on top of each other. Such graphene layer structures disclosed herein are distinct from graphite since the layer structures retain graphene-like properties. Graphene is a desirable material to form since it has advantageous electrical properties and can be used on a substrate for a wide range of electronic devices.

The method relies upon a substrate having Si—OH and/or Si—H moieties on a surface thereof. Preferably the substrate is a silicon-comprising substrate.

Examples of suitable silicon-containing substrates are fused silica, quartz, glass, or silicon-containing polymer substrate. The substrate may have a diameter (the standard measurement in the industry) of at least 2 inches and typically from 2 to 24 inches, preferably at least 6 inches or at least 8 inches. However, in principle there is no upper limit to the size which can be achieved beyond the size of the treatment chambers.

The Si—OH and/or Si—H moieties are preferably obtained by activating the surface of the substrate with a gas phase reaction to generate the Si—H and/or Si—OH groups. Preferably the substrate is pre-activated to introduce the Si—OH and/or Si—H moieties on the surface with an acid and/or peroxide. Any reactive silanol inducing or hydroxylating solution would serve to activate the surface accordingly.

One exemplary way to achieve this activation is with a mixture of H2SO4 and H2O2, preferably in a ratio of about 3:1, and preferably in an aqueous solution at a concentration of about 30 wt %. This solution is particularly effective for activating a surface having silicon as a constituent component as it can clean organic residues and hydroxylate simultaneously.

If the surface requires pre-activation then it is desirable that after pre-activating the surface to introduce the Si—OH and/or Si—H moieties on the surface, and before contacting the surface of the substrate with the carbon-containing reagent, the surface is contacted with water vapour and then dried. This helps to stabilise the surface groups and to remove any undesirable activation reagents.

A carbon-containing reagent is then provided. Suitable carbon-containing reagents include an olefin or a halo-silane comprising one or more carbon containing groups.

Among halosilanes, chlorosilanes are discussed primarily herein since they are the easiest to obtain and work with. However, fluoro, bromo or iodo silanes would work as well. Preferably the halo-silane has the structure

RaXbHcSi

wherein:

each R is a C1-C4 alkyl,

each X is selected from Cl, Br and I,

a is 1, 2 or 3,

b is 1 or 2,

c is 0, 1, or 2 and

a+b+c=4.

Most preferably the halo-silane is selected from the group consisting of: (CH3)3SiCl, (CH3)2SiCl2, (CH3)2SiHCl, and (CH3)H2SiCl

Suitable olefins include linear alpha-olefin, preferably wherein the olefin is a linear C3-C6 alpha-olefin. Any olefin that contains a CH3 radical is suitable, for example, Propylene, Butylene, Hexene, Pentene etc. It may also be possible to use compounds containing CH2 (Methylene) radicals. However, given the increased stability this process would likely be less efficient.

The carbon-containing reagent is contacted with the surface of the substrate to form a carbon-containing coating attached to the Si—OH and/or Si—H moieties on the surface. Preferably this reaction takes place in the gas phase. Preferably the step of contacting the surface of the substrate with the carbon-containing reagent is conducted at a temperature of from 10 to 80° C., preferably about 60° C. This range of temperatures is easier to work with and demonstrates the simplicity of the method disclosed herein.

Preferably contacting the carbon-containing reagent with the surface is performed in a single continuous step by flowing the, preferably gas phase, carbon-containing reagent across the surface of the substrate. The technique is distinct from ALD which relies on step-wise reactions of reagents with intervening flushing steps used to remove undesirable byproducts and/or excess reagents. The present invention does not involve such flushing steps. ALD is particularly unsuitable for the use of reagents with low vapour pressures such as silanes, which would take undue time to remove from the reaction chamber.

By coating it is meant that at least some regions of the surface are provided with the carbon-containing reagent. It will generally be desired that the entire surface is coated, but the coating can equally be provided using a mask to ensure that only targeted regions are coated.

One or more metals are then deposited onto the coated surface to form a metal layer on the coated surface. Depositing can be conducted by one of several different well-known techniques, including sputtering. Sputtering is a well-known technique in the art. Suitable deposition techniques also include electron-beam, PVD or magnetron sputtering, as well as simple sputtering, or thermal or vacuum sputtering. Preferably the one or more metals are d-block metals, preferably selected from the group consisting of copper, cobalt, gold, nickel and platinum, preferably copper and/or cobalt. Copper and cobalt are cheap and able to catalyse the formation of the graphene.

The deposition of the one or more metals is performed to achieve a metal layer. The total thickness of the metal layer is preferably from 5 to 200 nm, preferably 30 to 100 nm. Preferably the metal layer comprises one or more sublayers formed from different metals, preferably each sublayer having a thickness of from 5 to 50 nm. Again, it will generally be desired that the entire surface is provided with the metal layer, but the metal layer can equally be provided using a mask or with targeted deposition to ensure that only targeted regions are provided with the layer.

The method then involves heating the substrate under an inert atmosphere to thereby decompose the carbon-containing coating to form a metal-coated graphene layer on the substrate. Any regions without the metal layer to catalyse the decomposition will not form graphene. Preferably the step of heating the substrate under an inert atmosphere is conducted at a temperature of from 350° C. to 900° C., preferably 700 to 900° C., preferably under a hydrogen atmosphere. Use of a hydrogen atmosphere helps to avoid unwanted side reactions or oxidation.

In a particularly preferred embodiment the substrate is a fused silica, quartz, or silicon-containing polymer substrate and is pre-activated to introduce Si—OH and/or Si—H moieties on the surface with an acid and/or peroxide.

Preferably the method further comprises etching the metal-coating from the metal-coated graphene layer. This provides a good way of achieving a graphene layer on a substrate without contamination with metals since the metal layer can be cleanly etched away. Again, it will generally be desired that the entire surface is etched, but the metal layer can equally be etched using a mask to ensure that only targeted regions are etched.

After the final graphene layer has been formed, it may be desirable to cut the substrate into pieces for forming individual electronic devices. Alternatively, the graphene may be used as a substrate for the further formation of electronic devices.

It is also possible to use a laser to selectively ablate graphene from the surface in order to define electronic devices or circuitry. When using a laser to selectively ablate graphene from the substrate, suitable lasers are those having wavelength in excess of 600 nm and a power of less than 50 Watts. Preferably the laser has a wavelength of from 700 to 1500 nm. Preferably the laser has a power of from 1 to 20 Watts. This allows the graphene to be readily removed without damaging the neighbouring graphene or the substrate.

One suitable device which can be made by laser ablation is a Hall effect sensor. A hall effect sensor is a well-known component in the art. it is a transducer that varies its output voltage in response to a magnetic field. Hall effect sensors are used for proximity switching, positioning, speed detection, and current sensing applications. In a Hall effect sensor a thin strip of a conductor has a current applied along it, in the presence of a magnetic field the electrons are deflected towards one edge of the conductor strip, producing a voltage gradient across the short-side of the strip (perpendicular to the feed current). In contrast to inductive sensors, Hall effect sensors have the advantage that they can detect static (non-changing) magnetic fields.

Accordingly, optionally the method further comprises using a laser to selectively ablate graphene to thereby define a hall-sensor portion of the graphene on the substrate. More preferably the method is for use in the provision of a plurality of Hall sensor portions on the substrate. This would allow multiple detectors on the same substrate, or for the substrate to then be divided by conventional means into a plurality of sensors.

### EXAMPLES

The present invention will now be described further with reference to the following non-limiting examples.

This example demonstrates an embodiment of the method disclosed herein. The product is a silica substrate with a graphene multi-layer structure thereon.

The experiment used the following readily available materials:

1) Fused silica or quartz substrate: epi-ready, surface cleaned preferable (if not cleaning will be required)

2) Piranha solution—H2SO4:H2O2 (30% wt) @ 3:1

3) Silanes: (CH3)3SiCl, (CH3)2SiCl2, (CH3)2SiHCl, (CH3)H2SiCl

4) Sputter targets (Cu & Co)

The experiment used the following readily available equipment:

1) Piranha acid handling kit

2) Sealed chamber capable of being heated to ˜200° C. and flowing water vapour, nitrogen (or argon) and silane precursors

3) Sputter tool to deposit metal layers (e-beam, PVD, magnetron sputtering would also be appropriate, as long as thickness is controllable (sputter targets probably required)

4) Annealing chamber, capable of RTA/RTP under H2 (hydrogen essential)

5) Metal etching handling kit (pyrex system probably appropriate)

6) Graphene detection/test and measurement system (Raman)

The experiment used the following method steps:

1) Activate surface using piranha solution to create Si—OH groups (room temperature or above; room temperature preferred)

2) Heat wafer in a chamber to 100-200° C.

3) Introduce water vapour flow to chamber for 5-7 minutes (heat water and flow into chamber as gas steam)

4) Introduce inert gas flow (Ar/N2) for 5 minutes (remove any excess water—surface wants/needs to be dry to limit acid formation in next step)

5) Cool substrate to RT (60° C. would be better) Introduce Chloro-silane to react with Si—OH to form Si—O—SiR3 on the surface (e.g. ChloroTrimethyl Silane (CH3)3SiCl, DichloroDimethySilane (CH3)2SiCl2, Chlorodimethylsilane (CH3)2SiHCl, MethylChlorosilane (CH3)H2SiCl)

6) Sample can now be cooled and surface should be stable for transferral to next processes

7) Sputter thin layer of Cu/Co onto the substrate (30-50 nm of each),

8) Higher temperature (˜800° C.) anneal substrate in H2 gas for 10 minutes to form graphene at the SiO2/Cu interface.

NOTE: Anneal temperature can be lower if ramp rate can be increased, for example if 25° C./s can be achieved the anneal probably only needs to be 400° C.

9) Rapidly cool the substrate to RT (fast as possible) using, for example, high flow gas purge, or cooling surface if possible

10) Etch metal from substrate surface, using appropriate acid solution, to leave substrate and graphene layer

Exemplary substrate wafers include:

| | | |
|---|---|---|
| 1) | Knight optical: | Quartz Window, 16 mmdia × 1.5 mmthk |
| 2) | UQG Optics: | PFS 1010 (UV fused silica plate) |
| 3) | Pi-Kem: | Single crystal epi-ready 2″ quartz substrates |
| 4) | MicroChemicals | Single crystal epi-ready 2″ quartz substrates |
| | GmbH | |

All percentages herein are by weight unless otherwise stated.

The foregoing detailed description has been provided by way of explanation and illustration, and is not intended to limit the scope of the appended claims. Many variations in the presently preferred embodiments illustrated herein will be apparent to one of ordinary skill in the art, and remain within the scope of the appended claims and their equivalents.

1. A method for the production of graphene on a substrate, the method comprising:
providing a substrate having Si—OH and/or Si—H moieties on a surface thereof;
providing a carbon-containing reagent;
contacting the carbon-containing reagent with the surface of the substrate to form a carbon-containing coating attached to the Si—OH and/or Si—H moieties on the surface,
depositing one or more metals onto the coated surface to form a metal layer on the coated surface,
heating the substrate under an inert atmosphere to thereby decompose the carbon-containing coating to form a metal-coated graphene layer on the substrate.

2. The method according to claim 1, wherein the substrate is a silicon-comprising substrate.

3. The method according to claim 2, wherein the substrate is a fused silica, quartz, glass, or silicon-containing polymer substrate.

4. The method according to claim 2 further comprising pre-activating the substrate surface to introduce the Si—OH and/or Si—H moieties on the surface with an acid and/or peroxide.

5. The method according to claim 4, wherein the substrate is pre-activated to introduce the Si—OH and/or Si—H moieties on the surface with a mixture of H₂SO₄ and H₂O₂.

6. The method according to claim 4, wherein, after pre-activating the surface to introduce the Si—OH and/or Si—H moieties on the surface, and before contacting the surface of the substrate with the carbon-containing reagent, the surface is contacted with water vapour and then dried.

7. The method according to claim 1, wherein the step of contacting the surface of the substrate with the carbon-containing reagent is conducted at a temperature of from 10 to 80° C.

8. The method according to claim 1, wherein the carbon-containing reagent is an olefin or a halo-silane comprising one or more carbon containing groups.

9. The method according to claim 8, wherein the carbon-containing agent is a halo-silane and has the structure
RₐX_{b}H_{c}Si
wherein:
each R is a C1-C4 alkyl,
each X is selected from Cl, Br and I,
a is 1, 2 or 3,
b is 1 or 2,
c is 0, 1, or 2 and
a+b+c=4.

10. The method according to claim 8, wherein the carbon-containing agent is a linear alpha-olefin.

11. The method according to claim 1, wherein the one or more metals are selected from the group consisting of copper, cobalt, gold and platinum.

12. The method according to claim 1, wherein the step of depositing one or more metals comprises the use of an electron-beam, PVD, magnetron sputtering or sputtering.

13. The method according to claim 1, and wherein the metal layer:
(i) has a total thickness of from 5 to 200 nm; and/or
(ii) comprises one or more sublayers formed from different metals, each sublayer having a thickness of from 5 to 50 nm.

14. The method according to claim 1, wherein the step of heating the substrate under an inert atmosphere is conducted at a temperature of from 350° C. to 900° C.

15. The method according to claim 1, the method further comprising etching the metal-coating from the metal-coated graphene layer.

16. The method according to claim 8, wherein the carbon-containing agent is a halo-silane selected from the group consisting of (CH₃)₃SiCl, (CH₃)₂SiCl₂, (CH₃)₂SiHCl, and (CH₃)H₂SiCl.

17. The method according to claim 8, wherein the carbon-containing agent is a linear C3-C6 alpha-olefin.

18. The method according to claim 1, wherein the step of heating the substrate under an inert atmosphere is conducted at a temperature of from 700 to 900° C. under a hydrogen atmosphere.

19. The method according to claim 1, wherein the one or more metals are selected from the group consisting of copper and cobalt.

20. The method according to claim 1, wherein:
the substrate is a fused silica, quartz, glass, or silicon-containing polymer substrate;
the carbon-containing agent is a halo-silane selected from the group consisting of (CH₃)₃SiCl, (CH₃)₂SiCl₂, (CH₃)₂SiHCl, and (CH₃)H₂SiCl, or a linear C3-C6 alpha-olefin;
the step of heating the substrate under an inert atmosphere is conducted at a temperature of from 700 to 900° C. under a hydrogen atmosphere;
the one or more metals are selected from the group consisting of copper and cobalt;
the step of heating the substrate under an inert atmosphere is conducted at a temperature of from 700 to 900° C. under a hydrogen atmosphere; and
the method further comprises pre-activating the substrate surface to introduce the Si—OH and/or Si—H moieties on the surface with an acid and/or peroxide.
